(19) United States
(12) Patent Application Publication
(10) Pub. No.: US 2023/0400626 A1
(43) Pub. Date: Dec. 14, 2023

(54) OPTICAL MODULE AND OPTICAL COMMUNICATION DEVICE

(71) Applicant: Fujitsu Limited, Kawasaki-shi (JP)

(72) Inventors: Akio SUGAMA, Atsugi (JP); Yasuhiro NAKASHA, Hadano (JP)

(73) Assignee: Fujitsu Limited, Kawasaki-shi (JP)

(21) Appl. No.: 18/181,602

(22) Filed: Mar. 10, 2023

(30) Foreign Application Priority Data
Jun. 13, 2022 (JP) 2022-095203

(51) Int. Cl. G02B 6/12; H05K 1/02

(52) U.S. Cl. CPC G02B 6/12; H05K 1/0274; H05K 2201/10378; H05K 2201/10121

(57) ABSTRACT

An optical module including: a photonic integrated chip in which an optical circuit is formed; an electronic integrated chip that drives the photonic integrated chip; and an interposer that electrically couples the photonic integrated chip and the electronic integrated chip, wherein the photonic integrated chip is arranged on a side of a first main surface of the interposer, and the electronic integrated chip is arranged on a side of a second main surface on an opposite side of the first main surface, and the interposer includes a power supply layer, a first power supply via coupled to the power supply layer and configured to supply a first power supply voltage to the photonic integrated chip, and a second power supply via coupled to the power supply layer and configured to supply a second power supply voltage to the electronic integrated chip.

### CROSS-REFERENCE TO RELATED APPLICATION

This application is based upon and claims the benefit of priority of the prior Japanese Patent Application No. 2022-95203, filed on Jun. 13, 2022, the entire contents of which are incorporated herein by reference.

### FIELD

The embodiment discussed herein is related to an optical module and an optical communication device.

### BACKGROUND

Optical signals are suitable for high-speed, high-capacity signal transmission, and are widely used in fields of information and communication. In recent years, owing to progress of a silicon photonics technology in which fine optical circuits are densely integrated over a silicon chip, elements having higher functionality and smaller size than ever before have been manufactured. Demand for data transmission has also increased, and instead of simple on-off keying (OOK) using “1” and “0”, various modulation methods have been adopted in place, such as pulse amplitude modulation (PAM), quadrature phase shift keying (QPSK), and quadrature amplitude modulation (QAM).

In addition to the diversification of the modulation methods, an amount of data transmitted through a single optical fiber is increased by wavelength division multiplexing (WDM) transmission. As a modulation multilevel or the number of wavelengths to be multiplexed increases, an optical module is also needed to have a more complicated circuit configuration. A complicated optical circuit is implemented as a compact photonic integrated chip (PIC) by the silicon photonics technology.

A configuration is known in which signals supplied from a printed circuit board (PCB) are coupled to a PIC via an interposer and an electronic integrated chip (EIC). Furthermore, a configuration is known in which a power supply voltage supplied from an interposer is supplied to an optical circuit at a surface of an element and an EIC through a through-silicon via (TSV) penetrating a photonic integrated chip in a vertical direction.

Examples of the related art include: Japanese Laid-open Patent Publication No. 2015-216169; Japanese Laid-open Patent Publication No. 2015-130503; and Japanese National Publication of International Patent Application No. 2018-509753.

### SUMMARY

According to an aspect of the embodiments, there is provided an optical module including: a photonic integrated chip in which an optical circuit is formed; an electronic integrated chip that drives the photonic integrated chip; and an interposer that electrically couples the photonic integrated chip and the electronic integrated chip, wherein the photonic integrated chip is arranged on a side of a first main surface of the interposer, and the electronic integrated chip is arranged on a side of a second main surface on an opposite side of the first main surface. In an example, the interposer includes: a power supply layer, a first power supply via coupled to the power supply layer and configured to supply a first power supply voltage to the photonic integrated chip, and a second power supply via coupled to the power supply layer and configured to supply a second power supply voltage to the electronic integrated chip.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram of an optical module of an embodiment;

FIG. 2 is a schematic diagram of an optical communication device using the optical module of FIG. 1;

FIG. 3 is a schematic block diagram of the optical communication device of FIG. 2;

FIG. 4A is an assembly process diagram of the optical communication device;

FIG. 4B is an assembly process diagram of the optical communication device;

FIG. 4C is an assembly process diagram of the optical communication device;

FIG. 4D is an assembly process diagram of the optical communication device;

FIG. 4E is an assembly process diagram of the optical communication device;

FIG. 4F is an assembly process diagram of the optical communication device;

FIG. 4G is an assembly process diagram of the optical communication device;

FIG. 4H is an assembly process diagram of the optical communication device;

FIG. 5 is a schematic diagram of an optical communication device of a modification;

FIG. 6 is a diagram illustrating simulation results of the optical communication devices of the embodiment and a comparative example;

FIG. 7A is a diagram illustrating a configuration example of the comparative example of FIG. 6; and

FIG. 7B is a diagram illustrating another configuration example of the comparative example of FIG. 6.

### DESCRIPTION OF EMBODIMENTS

A dedicated electronic integrated chip (EIC) is used to operate the PIC. From a viewpoint of signal quality (signal integrity), it is desirable that the EIC is coupled to a corresponding circuit element of the PIC at the shortest distance. To keep the signal integrity high, it is important to keep quality of a power supply voltage (power integrity) supplied to the EIC and the PIC high. When the power supply voltage is supplied through a wiring layer with high resistance, a voltage drop due to a current occurs, and a voltage level supplied to an element and a circuit fluctuates. When the element and the circuit operate with an unstable power supply, the signal quality deteriorates.

To provide a stable power supply, it is desirable to use a wiring with low resistance. In a case where the power supply voltage is supplied via the EIC, wirings of or near an outermost layer with low resistance are effective to supply the power supply voltage. But they may be used for transmission and reception of a main signal, then it is difficult to allocate all the wirings near the outermost layer to supply the power supply voltage. On the other hand, a through-silicon via (TSV) vertically penetrating a photonic integrated chip is a thin wiring with a diameter of several microns to several tens of microns. To supply a large current by using the TSV, a large number of TSVs are needed. Furthermore, stress is generated around the TSV due to a difference in a thermal expansion coefficient between a silicon substrate and the TSV. Due to this stress, a refractive index of a silicon waveguide changes in a complicated manner, and the silicon waveguide does not exhibit designed operation. To avoid this, it is needed to arrange the silicon waveguide at a position away from the TSV. When the large number of TSVs are provided in the PIC, an area for optical circuit formation is narrowed, and the PIC is enlarged.

An object of one aspect of the present disclosure is to provide an optical module that implements stable supply of a power supply voltage and an optical communication device using the same.

In an optical module of an embodiment, a photonic integrated chip having an optical circuit formed therein is provided to one main surface of an interposer, and an electronic integrated chip that drives the photonic integrated chip is provided to a main surface on an opposite side of the interposer. Here, the “main surfaces” are surfaces substantially orthogonal to a thickness direction of a substrate, and are surfaces used for electrical and mechanical coupling with the photonic integrated chip and the electronic integrated chip. By directly supplying a power supply voltage to each of the photonic integrated chip and the electronic integrated chip from a wiring for power supply formed in the interposer, stable supply of the power supply voltage is implemented.

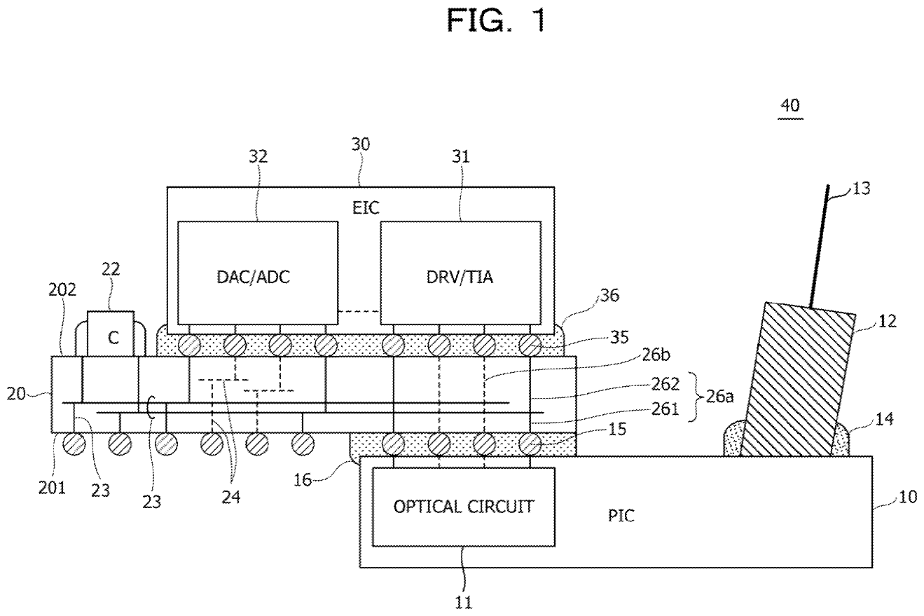

FIG. 1 is a schematic diagram of an optical module 40 of the embodiment. The optical module 40 includes a photonic integrated chip (denoted as “PIC” in the drawing) 10 in which an optical circuit 11 is formed, an electronic integrated chip (denoted as “EIC” in the drawing) 30 that drives the photonic integrated chip 10, and an interposer 20 that electrically couples the photonic integrated chip 10 and the electronic integrated chip 30. The photonic integrated chip 10 is provided to a first main surface 201 of the interposer 20, and the electronic integrated chip 30 is provided to a second main surface 202 on an opposite side of the first main surface 201.

The optical circuit 11 formed in the photonic integrated chip 10 is coupled to the first main surface 201 of the interposer 20 by bump electrodes and the coupling is enhanced by an underfill 16. The electronic integrated chip 30 includes an electric circuit (denoted as “DRV/TIA” in the drawing) 31 electrically coupled to the optical circuit 11, and a signal processing circuit (denoted as “DAC/ADC” in the drawing) 32 that performs high-speed signal processing with an external electronic component. In the electric circuit 31, electronic circuits such as a driver that drives an optical element included in the optical circuit 11 and a transimpedance amplifier (TIA) that converts a photocurrent generated in the optical circuit 11 into a voltage signal are formed. The signal processing circuit 32 includes a digital-to-analog converter (DAC) and an analog-to-digital converter (ADC).

The electric circuit 31 and the signal processing circuit 32 are coupled to the second main surface 202 of the interposer 20 by bump electrodes 35, and the coupling is enhanced by an underfill 36. A component 22 such as a decoupling capacitor for power supply enhancement may be mounted to the second main surface 202 of the interposer 20.

In the interposer 20, power supply and ground wirings (hereinafter, may be referred to as “power supply/ground wirings”, “power supply layer”, or the like) 23 and signal lines 24 are formed. For convenience, the power supply/ground wirings that supply a power supply voltage and ground potential are indicated by thick solid lines, and wirings that transmit signals are indicated by thick dotted lines. The power supply voltage is directly supplied to each of the photonic integrated chip 10 and the electronic integrated chip 30 from a power supply wiring of the power supply/ground wirings 23. From a viewpoint of power supply to the photonic integrated chip 10 and the electronic integrated chip 30, the interposer 20 is desirably a substrate including a multilayer wiring, and a substrate of resin, ceramic, silicon, glass, or the like may be used. The power supply/ground wiring 23 is, for example, a wiring with low resistance formed by etching a copper foil, and is electrically coupled to the bump electrodes 15 and 35.

The power supply/ground wirings 23 are formed in a wiring layer parallel to the first main surface 201 and the second main surface 202 of the interposer 20. This wiring layer is formed of a copper foil or the like, as described above, is thicker than a normal large-scale integration (LSI) wiring, and has a high degree of freedom in selection. For example, by setting a thickness of the power supply/ground wiring 23 to 30 to 60 μm, the thickness may be made 30 times that of a common LSI wiring layer used in the electronic integrated chip 30. The thickness of the power supply/ground wiring 23 is also thicker than a thickness of an electrode or wiring provided in the photonic integrated chip 10. By directly supplying the power supply voltage to each of the photonic integrated chip 10 and the electronic integrated chip 30 from the power supply/ground wirings 23 with low resistance having a sufficient thickness, stable power supply is implemented.

The wiring layer of the interposer 20 may also be a solid pattern. In this case, wiring resistance may be lowered by two orders of magnitude or more. As for the power supply/ground wirings 23, common techniques that stabilize a power supply may be used, such as pairing a power supply plane with a ground plane or sandwiching a power supply plane between ground planes.

The power supply voltage is supplied to the photonic integrated chip 10 and the electronic integrated chip 30 by via wirings 26a extending in a vertical direction of the interposer 20 from the power supply/ground wirings 23. The via wiring 26a includes a first via wiring 261 that supplies the power supply voltage to the photonic integrated chip 10, and a second via wiring 262 that supplies the power supply voltage to the electronic integrated chip 30. The first via wiring 261 is an example of a first power supply via that is coupled to the power supply/ground wiring 23 and supplies a power supply voltage for a photonic integrated chip to the photonic integrated chip. The second via wiring 262 is an example of a second power supply via that is coupled to the power supply/ground wiring 23 and supplies a power supply voltage for an electronic integrated chip to the electronic integrated chip. The via wiring 26a is sufficiently large in diameter compared to a through-silicon via (TSV), and for example, a filled via (via filled with copper plating inside) with a diameter of 100 μm may be used. A cross-sectional area of one filled via with a diameter of 100 μm corresponds to 100 TSVs with a diameter of 10 μm.

The power supply from the power supply/ground wirings 23 to the electronic integrated chip 30 may use not only a pair of via wirings 26a of the power supply wiring and the ground wiring, but also a large number of via pairs. It is also possible to allocate all unused via wirings 26a for the power supply to the electronic integrated chip 30. With this configuration, stable power integrity may be expected.

By the configuration of FIG. 1, power supply corresponding to thousands to tens of thousands of TSVs is implemented. In a configuration in which a TSV for power supply is provided in a photonic integrated chip, a keep-out zone that avoids waveguide formation is needed to avoid an influence of stress caused by a difference in a thermal expansion coefficient between the TSV and silicon. The keep-out zone is set at least three times a diameter of the TSV, and it is not possible to effectively use an optical circuit formation area. On the other hand, since the via wirings 26a in the vertical direction, which are the power supply wirings of the interposer 20, are coupled to the optical circuit 11 via the bump electrodes 15, the photonic integrated chip 10 does not need to be provided with a keep-out zone. In the photonic integrated chip 10, a formation area of the optical circuit 11 may be effectively used.

The optical circuit 11 of the photonic integrated chip 10 and the electric circuit 31 of the electronic integrated chip 30 are coupled at the shortest distance by via wirings 26b for signals, which penetrate through the interposer 20 in a thickness direction. Since signals between the optical circuit 11 and the electric circuit 31 are vulnerable to noise, it is desirable to arrange the optical circuit 11 and the electric circuit 31 at corresponding positions with the interposer 20 interposed therebetween and couple them by a straight path. Even when the via wirings 26b coupling the optical circuit 11 and the electric circuit 31 are formed as through vias, signal wirings with a sufficiently large diameter and with low resistance may be obtained. The use of the interposer 20 is advantageous in terms of signal transmission as well as supply of the power supply voltage.

Paths of both the signal lines 24 and the power supply/ground wirings 23 are lengthened by the thickness of the interposer 20. However, even when the path lengths are increased by the thickness of the interposer 20, it has little influence on deterioration in the signal integrity and the power integrity. This is because the influence of such increase in the path lengths is within a range that may be covered by design, and does not interfere with operation of the optical module 40.

In the configuration of FIG. 1, the photonic integrated chip 10 and the interposer 20 overlap only in a region where the optical circuit 11 is formed. The photonic integrated chip 10 is coupled to an optical fiber 13 held by a ferrule 12 in a region other than the optical circuit 11. A plurality of the optical fibers 13 may be held by the ferrule 12. The ferrule 12 is fixed to the surface of the photonic integrated chip 10 with an adhesive 14, and a tip of the optical fiber 13 is optically coupled to an optical coupler formed at the photonic integrated chip 10. The optical fiber 13 and the ferrule 12 may be coupled after the optical module 40 is mounted to a main substrate, as will be described later.

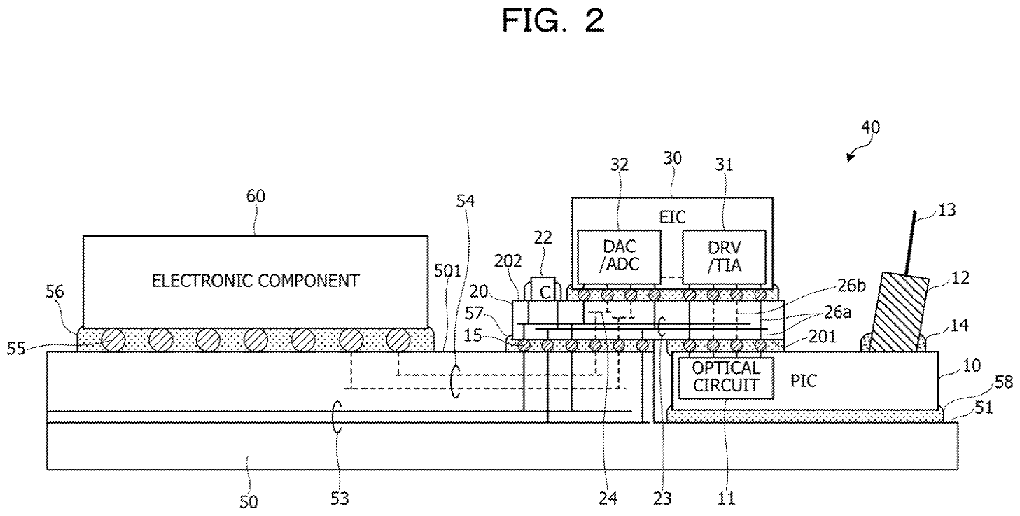

FIG. 2 is a schematic diagram of an optical communication device 100 using the optical module 40 of FIG. 1. The optical communication device 100 includes a main board 50 and the optical module 40 mounted to the main board 50. The main board 50 may be a motherboard, a package substrate, a copackage mounting substrate, or the like. A step 51 is formed at a mounting surface 501 of the main board 50 to which the optical module 40 is mounted. The photonic integrated chip 10 of the optical module 40 is positioned at the step 51. A region of the interposer 20 that does not overlap the photonic integrated chip 10 is bonded to the mounting surface 501 of the main board 50.

The interposer 20 is provided over the main board 50 and the photonic integrated chip 10 above the step 51. The power supply/ground wirings 23 formed in the interposer 20 are coupled to power supply/ground wirings 53 in the main board 50 via the bump electrodes 15. The signal lines 24 formed in the interposer 20 are coupled to signal lines 54 in the main board 50 via the bump electrodes 15.

An electronic component 60 is mounted to the mounting surface 501 of the main board 50 via bump electrodes 55. The coupling between the electronic component 60 and the main board 50 is enhanced by an underfill 56. The electronic component 60 is a central processing unit (CPU), a digital signal processor (DSP), a field programmable gate array (FPGA), a switching LSI, or the like. The electronic component 60 is coupled to the signal processing circuit 32 of the electronic integrated chip 30 via the signal lines 54 and the signal lines 24.

The signal lines 24 and 54 through which high-speed data passes are desirably the shortest. For example, it is desirable that the electronic component 60 and the electronic integrated chip 30 are coupled by the shortest path. Assuming that the electronic component 60 is the DSP, a digital data signal generated by the electronic component 60 is input to the signal processing circuit 32 through the bump electrodes 55, the signal lines 54, and the signal lines 24. The digital data signal is converted into an analog electrical signal by the signal processing circuit 32 and amplified by the electric circuit 31 to generate a drive signal that drives the optical circuit 11. The drive signal is input to the optical circuit 11 through the via wirings 26b, which are the signal lines 24 penetrating the interposer 20.

An optical signal input from the optical fiber 13 and received by the optical circuit 11 is input, as a photocurrent, to the electric circuit 31 of the electronic integrated chip 30 from the via wirings 26b of the interposer 20. The photocurrent is converted into a voltage signal by the electric circuit 31 and converted into a digital signal by the signal processing circuit 32. The digital signal is input to the electronic component 60 through the signal lines 24 of the interposer 20 and the signal lines 54 of the main board 50.

A power supply voltage is supplied to the interposer 20 from the power supply/ground wirings 53 of the main board 50. As described above, in the interposer 20, the plurality of power supply/ground wirings 23 is formed in the direction parallel to the substrate surfaces (the first main surface 201 and the second main surface 202), and a required power supply voltage is supplied from the power supply/ground wirings 23 to each of the electronic integrated chip 30 and the photonic integrated chip 10. It is also possible to form the power supply/ground wirings 23 of the interposer 20 as solid patterns, so that the power supply voltage may be stably supplied to both the electronic integrated chip 30 and the photonic integrated chip 10.

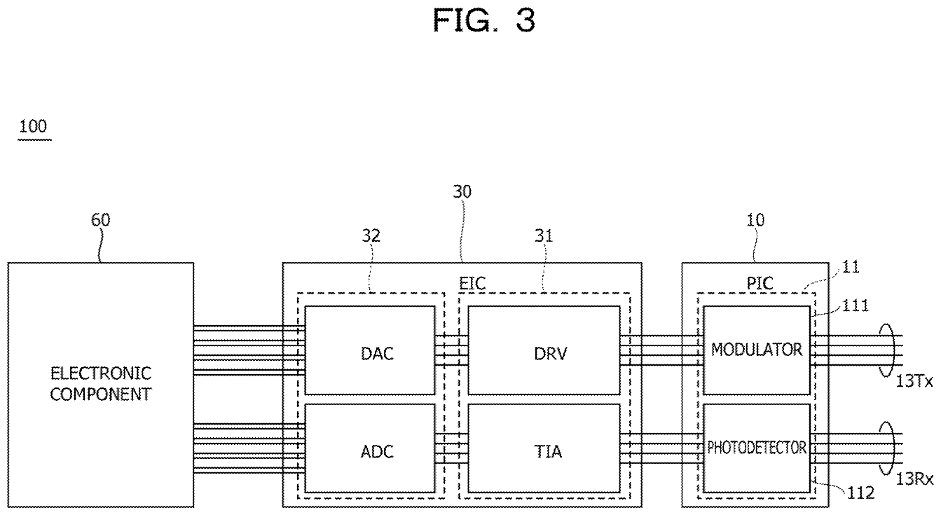

FIG. 3 is a schematic block diagram of the optical communication device of FIG. 2. The optical communication device 100 functions as an optical transceiver. The optical communication device 100 includes the electronic component 60, the electronic integrated chip 30, and the photonic integrated chip 10.

The optical circuit 11 of the photonic integrated chip 10 includes a modulator 111 on a transmission side and a photodetector 112 on a reception side. The electronic integrated chip 30 includes the driver (DRV) of the electric circuit 31 and the DAC of the signal processing circuit 32 on the transmission side, and the TIA of the electric circuit 31 and the ADC of the signal processing circuit 32 on the reception side.

A power supply voltage supplied to the photonic integrated chip may be used as, for example, a direct current (DC) bias applied to the modulator 111 or a bias voltage that operates the photodetector 112. An optical signal modulated by the modulator 111 is output to an optical fiber 13Tx on the transmission side. On the reception side, an optical signal entering the optical circuit 11 from an optical fiber 13Rx is detected by the photodetector 112 and output to the electric circuit 31 as a current signal.

A power supply voltage supplied to the electronic integrated chip is used to operate the electric circuit 31 and the signal processing circuit 32. The power supply voltage is used for a power supply voltage and a gate voltage of transistors constituting the driver (DRV) and the TIA of the electric circuit 31, and is also used as a power supply for the DAC and the ACD. The power supply voltage is directly supplied to each of the electronic integrated chip 30 and the photonic integrated chip 10 via the interposer 20, and stable supply of the power supply voltage is implemented.

<Assembly of Optical Communication Device>

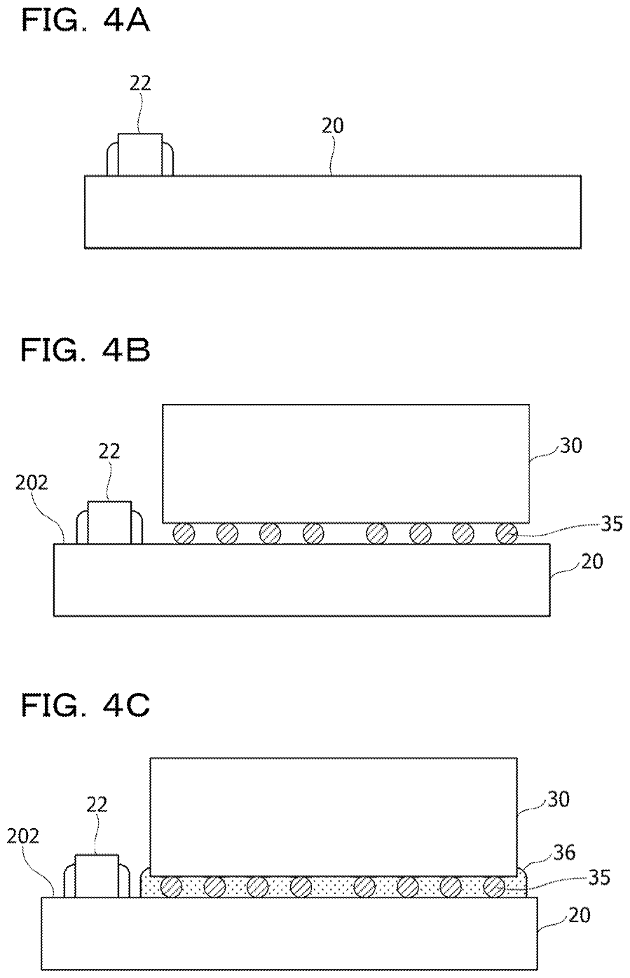

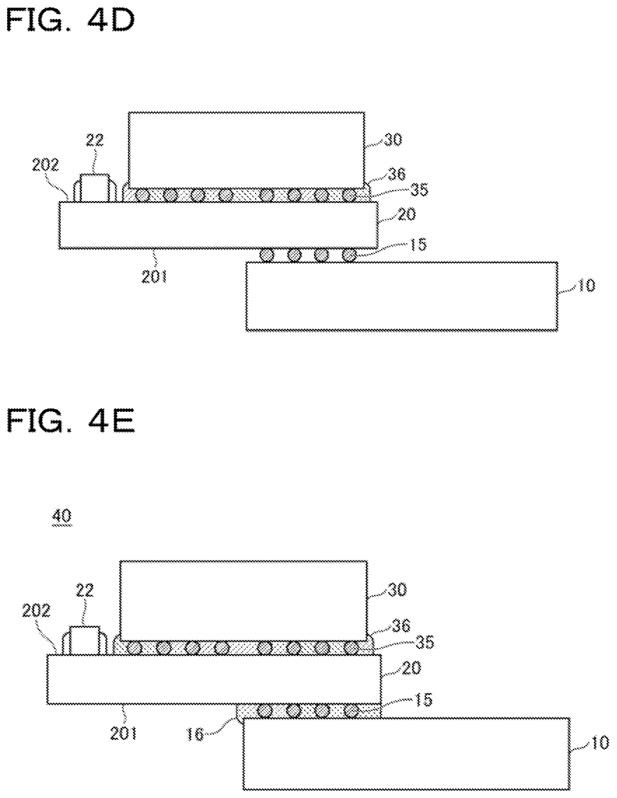

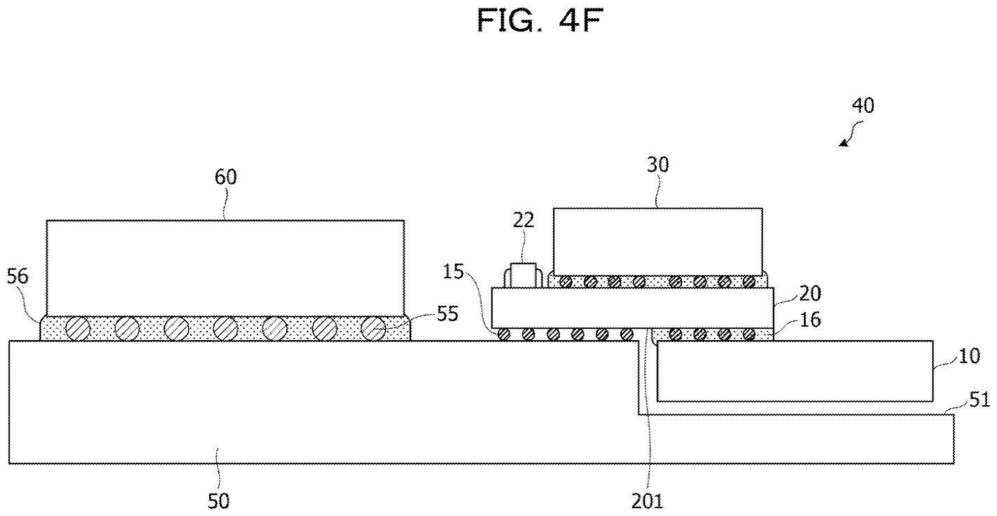

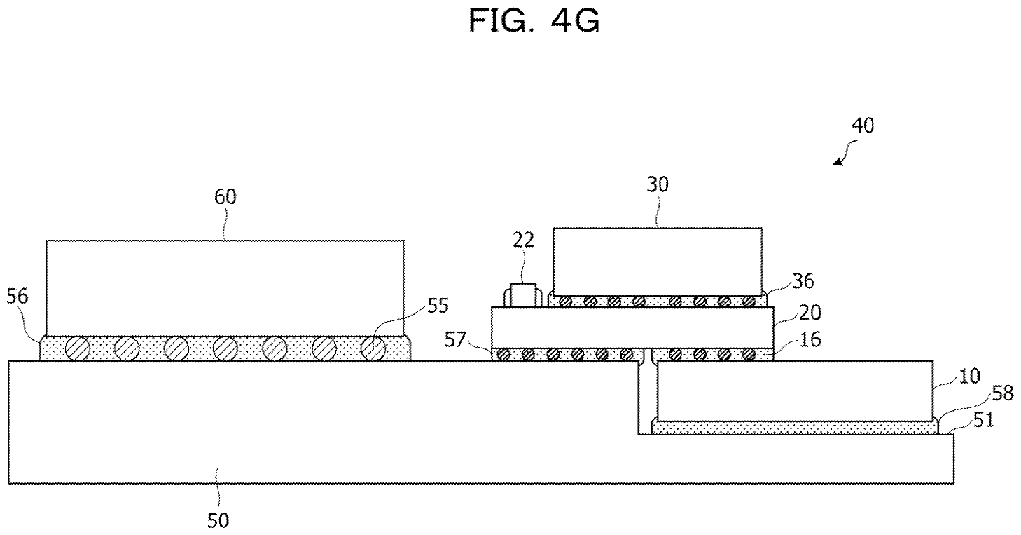

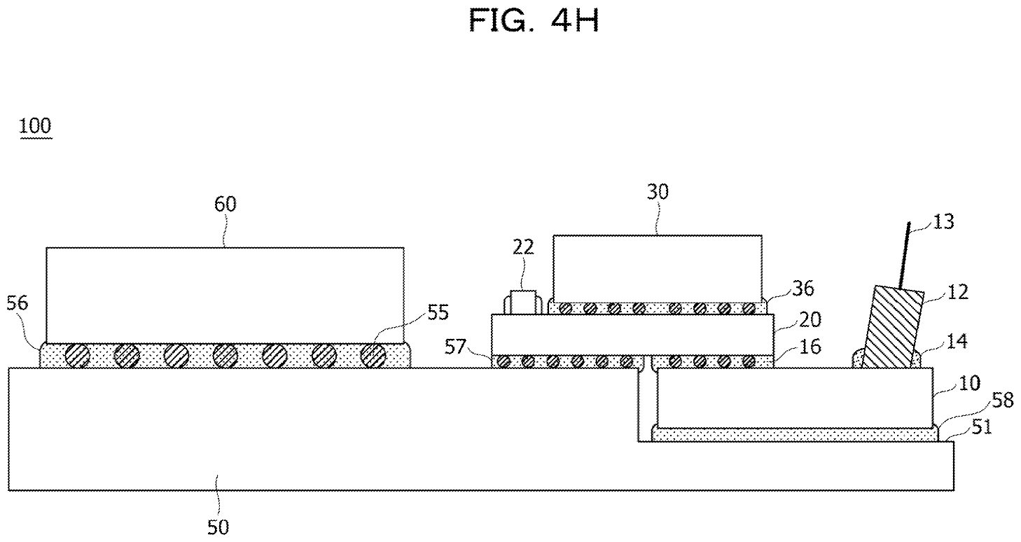

FIGS. 4A to 4H are assembly process diagrams of the optical communication device 100. Among these, FIGS. 4A to 4E relate to an assembly process of the optical module 40. In FIG. 4A, the component 22 is mounted on the interposer 20 as needed. The interposer 20 is manufactured by a known multilayer wiring substrate manufacturing method, for example, is formed by a subtractive method of etching a copper foil. The interposer 20 in which the power supply/ground wirings 23, the signal lines 24, and the via wirings 26a and 26b are formed is obtained by alternately bonding insulating layers and copper foils and processing them into an appropriate pattern. The mounting of the component on the interposer 20 is optional, but the component 22 such as a decoupling capacitor for power supply enhancement may be mounted.

In FIG. 4B, the electronic integrated chip 30 is flip-chip mounted (bonded) to the second main surface 202 of the interposer 20. In the electronic integrated chip 30, the electric circuit 31 and the signal processing circuit 32 described above are formed. A surface at which the electric circuit 31 and the signal processing circuit 32 are formed is aligned so as to face the second main surface 202 of the interposer 20, and is bonded by the bump electrodes 35 to an electrode pad provided to the second main surface 202. In FIG. 4C, an underfill material is injected into a space between the electronic integrated chip 30 and the interposer 20 and cured to form the underfill 36.

In FIG. 4D, the photonic integrated chip 10 is flip-chip mounted to the first main surface 201 of the interposer 20. A surface of the photonic integrated chip 10 at which the optical circuit 11 is formed is aligned so as to face the first main surface 201 of the interposer 20, and is bonded by the bump electrodes 15 to an electrode pad provided to the first main surface 201. In FIG. 4E, an underfill material is injected into a space between the photonic integrated chip 10 and the interposer 20 and cured to form the underfill 16.

The order in which the electronic integrated chip 30 and the photonic integrated chip 10 are mounted to the interposer 20 may be reversed. Which element is mounted first may be determined according to ease of manufacture. At the stage of FIG. 4E, for example, when the photonic integrated chip 10 and the electronic integrated chip 30 are mounted to the first main surface 201 and the second main surface 202 of the interposer 20, respectively, the optical module 40 is obtained.

In FIG. 4F, the optical module 40 is flip-chip mounted to the main board 50 to which the electronic component 60 is mounted in advance. The electronic component 60 is flip-chip mounted to the main board 50 by the bump electrodes 55. The bonding between the electronic component 60 and the main board 50 is enhanced by the underfill 56. The electronic component 60 is a CPU, a switching LSI, a DSP, an FPGA, or the like.

The optical module 40 is aligned so that the first main surface 201 faces the main board 50 in the region of the interposer 20 that does not overlap the photonic integrated chip 10, and is bonded by the bump electrodes to the main board 50. By this bonding, the photonic integrated chip 10 is positioned at the step 51 formed in the main board 50.

In FIG. 4G, an underfill material 57 is injected into a space between the interposer 20 and the main board 50, and an underfill material 58 is injected into a space between the photonic integrated chip 10 and the step 51, and the injected underfill materials 57 and 58 are cured. In FIG. 4H, the ferrule 12 holding the optical fiber 13 is fixed to the photonic integrated chip 10 by the adhesive 14. The optical fiber 13 serving as an external optical wiring is optically coupled to the optical coupler formed at the photonic integrated chip 10. Commonly, since the optical fiber 13 and the adhesive 14 for optics are vulnerable to high temperatures, the optical fiber 13 is coupled at the end of the assembly of the optical communication device 100. With this configuration, the optical communication device 100 is obtained.

In the optical communication device 100, the photonic integrated chip 10 and the electronic integrated chip 30 are coupled via the interposer 20 at the shortest distance. A power supply voltage supplied from the main board 50 is directly supplied to each of the photonic integrated chip 10 and the electronic integrated chip 30 from the power supply/ground wirings 23 (see FIG. 2) formed in the interposer 20. Stable power supply is implemented, and good signal quality is obtained in the optical communication device 100 or the optical module

<Modification of Optical Communication Device>

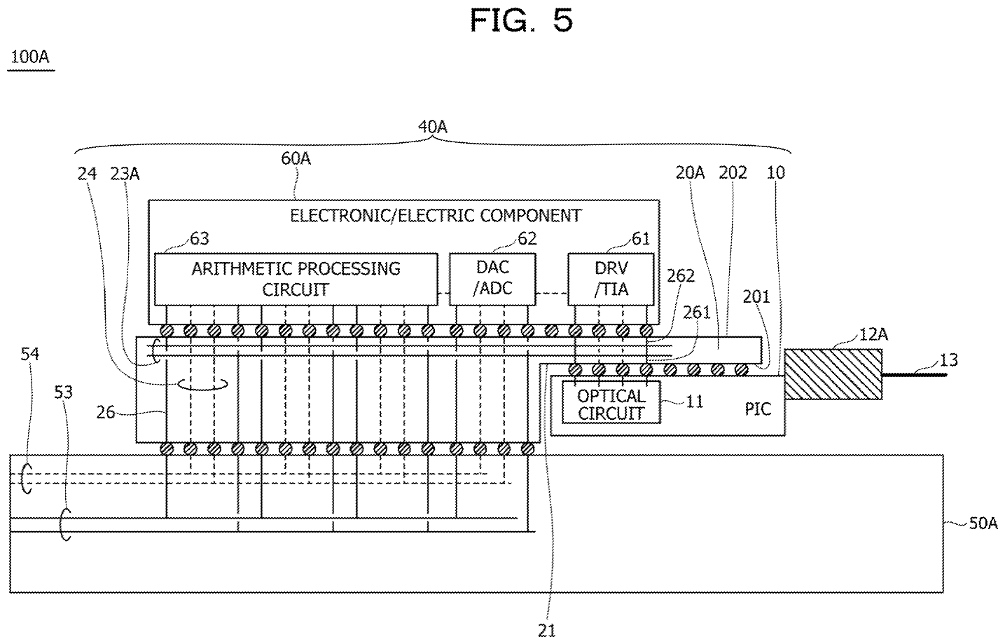

FIG. 5 is a schematic diagram of an optical communication device 100A of a modification. The optical communication device 100A includes an optical module 40A and a main board 50A to which the optical module 40 is mounted. In the configuration of FIG. 2, the step 51 is formed in the main board 50 to accommodate the photonic integrated chip 10 bonded to the first main surface 201 of the interposer 20. In the modification of FIG. 5, a step 21 is formed in an interposer 20A, and a photonic integrated chip 10 is coupled to the interposer 20A at the step 21.

The optical module 40A includes the photonic integrated chip 10 in which an optical circuit 11 is formed, an electronic/electric component 60A that drives and controls the photonic integrated chip 10, and the interposer 20A that electrically couples the photonic integrated chip 10 and the electronic/electric component 60A. The interposer 20A has a first main surface 201 in which the step 21 is formed and a second main surface 202 on an opposite side of the first main surface 201. The photonic integrated chip 10 is bonded to the first main surface 201, and the electronic/electric component 60A is bonded to the second main surface 202.

The electronic/electric component 60A includes an electric circuit 61 including a driver (DRV), a TIA, and the like, a signal conversion circuit 62 including a DAC, an ADC, and the like, and an arithmetic processing circuit 63. In the electronic/electric component 60A, the electric circuit 61 is provided at a position facing the optical circuit 11 with the step 21 of the interposer 20A interposed therebetween. The arithmetic processing circuit 63 has signal processing functions equivalent to those of a CPU, a DSP, a switching LSI, and the like.

The interposer 20A includes power supply/ground wirings 23A extending parallel to the second main surface 202 at a position close to the second main surface 202. The power supply/ground wirings 23A extend to the step 21 of the interposer 20A, and supply a power supply voltage directly to the optical circuit 11 of the photonic integrated chip 10. The power supply/ground wirings 23A also supply the power supply voltage directly to the electric circuit 61, the signal conversion circuit 62, and the arithmetic processing circuit 63 of the electronic/electric component 60A. A first via wiring 261 that is coupled to the power supply/ground wiring 23A and supplies a power supply voltage for a photonic integrated chip to the photonic integrated chip 10 functions as the first power supply via. A second via wiring 262 that is coupled to the power supply/ground wiring 23A and supplies a power supply voltage for an electronic/electric component to the electronic/electric component 60A functions as the second power supply via. The power supply/ground wirings 23A are formed as a solid film with a sufficient film thickness at or near an outermost surface of the interposer 20, and power supply wirings with low resistance are implemented.

The power supply/ground wirings 23A in a horizontal direction is coupled to power supply/ground wirings 53 of the main board 50A by via wirings 26 extending in a vertical (thickness) direction of the interposer 20A. The via wiring 26 has a large diameter of 100 μm, and a voltage drop is suppressed.

A large number of signal lines 24 extending in the vertical direction are formed in the interposer 20A. Among the signal lines 24 indicated by broken lines, the signal lines 24 extending in the direction perpendicular to the main surfaces at the step 21 couple the optical circuit 11 of the photonic integrated chip 10 and the electric circuit 61 of the electronic/electric component at the shortest distance. The signal lines 24 in the vertical direction provided in a region other than the step 21 penetrate the interposer 20A in the thickness direction, and couple the signal conversion circuit 62 and the arithmetic processing circuit 63 of the electronic/electric component 60A to signal lines 54 of the main board 50A at the shortest distance. The signal line 24 has a diameter of about 100 μm, which is sufficiently large, and may reliably perform high-speed signal transmission.

In the optical communication device 100A of FIG. 5, an optical fiber 13 is coupled to the photonic integrated chip 10 from the horizontal direction. A ferrule 12A holds the optical fiber 13 so that an end surface of the optical fiber 13 is coupled to an optical waveguide formed in the photonic integrated chip 10 at an end surface. With this configuration, the optical communication device 100A may operate with a stable power supply voltage and maintain good signal quality.

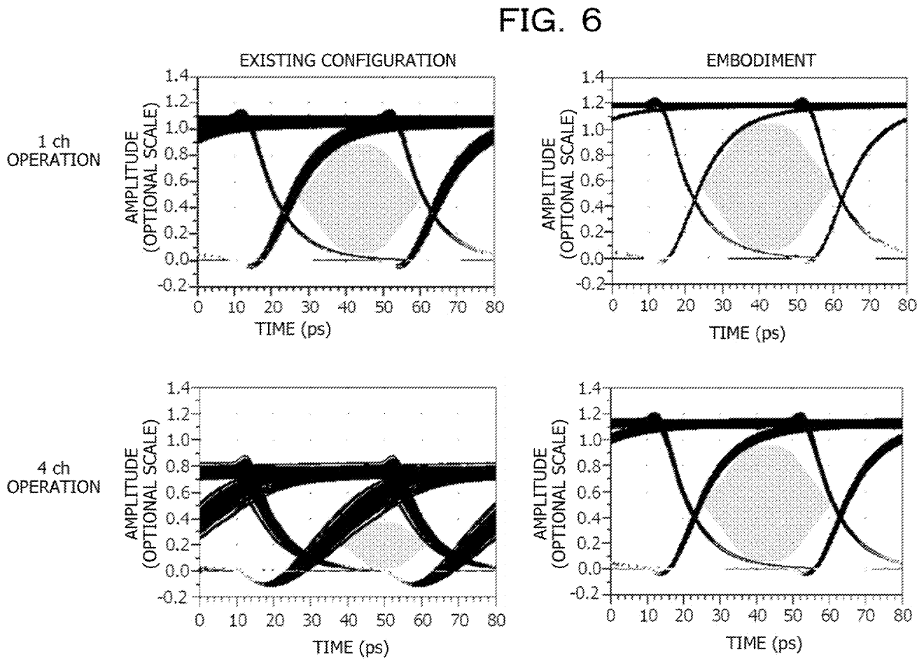

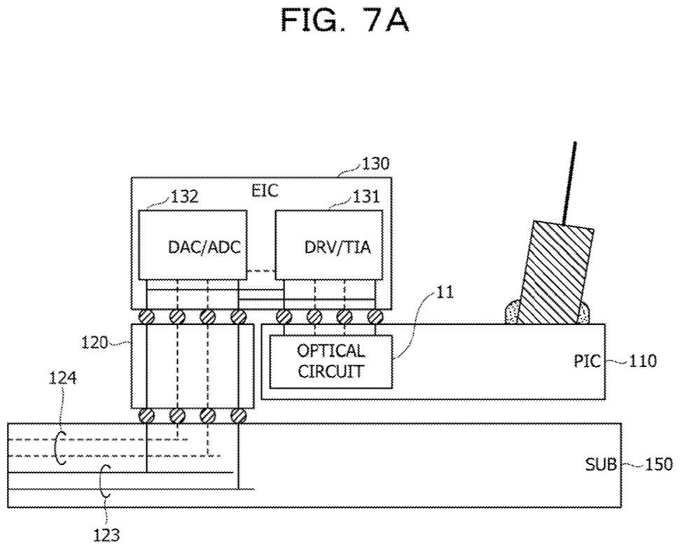

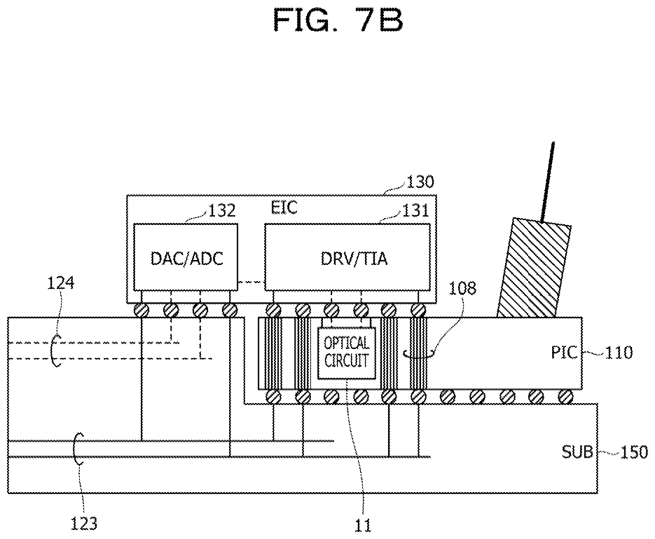

FIG. 6 illustrates simulation results of the optical communication devices of the embodiment and a comparative example. The optical communication device of the embodiment is the optical communication device 100 of FIG. 2, and a power supply voltage supplied from the main board 50 is directly supplied to each of the photonic integrated chip 10 and the electronic integrated chip 30 from the power supply/ground wirings 23 of the interposer 20. The optical communication device of the comparative example has a configuration of FIG. 7A or 7B.

In the comparative example of FIG. 7A, a power supply voltage supplied from power supply/ground wirings 123 of a substrate (denoted as “SUB” in the drawing) 150 passes through an interposer 120 and is supplied to an electronic integrated chip 130. Among the wirings passing through the interposer 120, thick solid lines are wirings for power supply/ground voltage supply, and thick dotted lines are signal wirings. A part of the power supply voltage supplied to the electronic integrated chip 130 is supplied from the electronic integrated chip 130 to a photonic integrated chip 110. Both a power supply voltage supplied to a signal processing circuit (DAC/ADC) 132 and an electric circuit (DRV/TIA) 131 of the electronic integrated chip 130 and the power supply voltage supplied from the electronic integrated chip 130 to the photonic integrated chip 110 depend on internal wirings of the electronic integrated chip 130.

Even when a wiring layer closest to a surface layer called global wirings is used as the internal wirings for supplying a power supply voltage, a thickness of the wiring is about 1 to 2 μm, and the number of wiring layers is as small as about two to three layers. Since these global wirings are also used for another signal transmission, it is not possible to allocate all the global wirings for power supply wirings. Moreover, as a limitation of an LSI process, it is needed to keep a pattern ratio per area below a certain level, so that use of a solid pattern is not possible. For these reasons, resistance of the internal wirings of the electronic integrated chip 130 is high, a voltage drop occurs due to a current, and a voltage reaching the electric circuit (DRV/TIA) 131 becomes small. When the current fluctuates in an operation state, the voltage reaching the electric circuit (DRV/TIA) 131 also fluctuates, and the electric circuit (DRV/TIA) 131 operates with an unstable power supply. Thus, a signal deteriorates.

In the comparative example of FIG. 7B, a power supply voltage supplied to the photonic integrated chip 110 from the power supply/ground wirings 123 of the substrate 150 is supplied to an optical circuit 11 through a TSV 108 penetrating the photonic integrated chip 110. The power supply voltage is supplied from the photonic integrated chip 110 to the electronic integrated chip 130. The TSV 108 is a thin wiring with a diameter of about 10 to 30 μm, and a large number of TSVs 108 are used to supply a large current. Each TSV 108 has high resistance, and the power supply voltage supplied to the electronic integrated chip 130 fluctuates. The TSV 108 also has a problem that it needs a keep-out zone for stress relief, which narrows an area where the optical circuit may be formed.

Returning to FIG. 6, in each of the comparative example and the embodiment, an eye pattern (eye diagram) of modulator drive output on the transmission side of the electronic integrated chip is simulated. The comparative example used in the simulation has the configuration of FIG. 7A. It is assumed that the optical module is 100 Gbps (25 Gbps×four channels). When only one channel is driven, a sufficient eye opening is observed in waveforms in both the embodiment and the comparative example. When four channels are driven simultaneously, in the comparative example, the eye opening becomes very small due to an influence of instability of power supply due to the internal wirings of the electronic integrated chip EIC. On the other hand, in the configuration of the embodiment, there is almost no change in the eye opening even when four channels are simultaneously driven. This indicates that sufficient power integrity is ensured.

Even when the configuration of the comparative example of FIG. 7B is used, in the simulation result, the eye opening becomes very narrow when four channels are simultaneously driven, similarly to the comparative example of FIG. 6. This is because when the TSV is used to supply the power supply voltage from the PIC to the EIC, the power supply becomes unstable due to the influence of the voltage drop caused by the current. Although it is possible to ensure the same level of power integrity as the embodiment with a large number of TSVs, but there is a trade-off with a loss of an optical circuit area due to the keep-out zone.

According to the optical module and the optical communication device of the embodiment, stable power supply maintains appropriate eye opening and good signal quality even in multi-channel optical communication. Under the increasing importance of the power integrity due to increasing data rates and complexity of signal processing, a power supply voltage is supplied directly from the interposer to each block that needs power supply. A change in a wiring length is about a thickness of the substrate of the interposer, and may be dealt with by design. With this configuration, it is possible to suppress deterioration in signal quality and ensure sufficient power integrity.

Although the embodiment has been described based on specific configuration examples, another modification is also included in the embodiment. For example, the signal processing circuit 32 of the electronic integrated chip 30 may be a DSP with DAC/ADC functions, and the electronic component 60 mounted to the main board 50 may be a switching LSI. In this case, a configuration may be adopted in which a plurality of optical modules is mounted to the main board 50 and coupling is switched by the switching LSI. Furthermore, an LSI or a CPU may be mounted to the main board 50 as the electronic component 60, and the optical communication device 100 may be used as a server blade. In either case, since stable power supply is implemented in the optical module, quality of signals generated by the optical module may be maintained.

In the configuration of FIG. 1, instead of coupling the optical fiber 13 from the vertical or oblique direction to the surface of the photonic integrated chip 10 to which the optical circuit 11 is provided, the optical fiber 13 may be coupled from the horizontal direction. In this case, the end surface of the optical fiber 13 and the end surface of the optical waveguide formed in the photonic integrated chip 10 may be optically coupled.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical module comprising:
a photonic integrated chip in which an optical circuit is formed;
an electronic integrated chip that drives the photonic integrated chip; and
an interposer that electrically couples the photonic integrated chip and the electronic integrated chip,
wherein the photonic integrated chip is arranged on a side of a first main surface of the interposer, and the electronic integrated chip is arranged on a side of a second main surface on an opposite side of the first main surface, and
the interposer includes a power supply layer, a first power supply via coupled to the power supply layer and configured to supply a first power supply voltage to the photonic integrated chip, and a second power supply via coupled to the power supply layer and configured to supply a second power supply voltage to the electronic integrated chip.

2. The optical module according to claim 1, wherein
the electronic integrated chip includes an electric circuit that drives the optical circuit, and
the photonic integrated chip and the electronic integrated chip are arranged at positions where the optical circuit and the electric circuit are coupled shortest by a signal line formed in the interposer.

3. The optical module according to claim 1, wherein
a thickness of the power supply layer in the interposer is thicker than a thickness of an internal wiring of the electronic integrated chip.

4. The optical module according to claim 1, wherein
a part of the photonic integrated chip is overlapped by the interposer, and an optical fiber is coupled to a region of the photonic integrated chip that is not overlapped by the interposer.

5. The optical module according to claim 4, wherein
the optical fiber is coupled from a substantially vertical or horizontal direction to a surface of the photonic integrated chip to which the optical circuit is provided.

6. The optical module according to claim 1, wherein
the interposer has a step in the first main surface, and
the photonic integrated chip is provided at the step.

7. The optical module according to claim 6, wherein
the power supply layer extends to the step in parallel with the second main surface near the second main surface, and at the step, the power supply voltage is supplied to the photonic integrated chip from the power supply layer by the first power supply via.

8. An optical communication device comprising:
a main board; and
an optical module mounted to the main board,
wherein the optical module includes:
a photonic integrated chip in which an optical circuit is formed;
an electronic integrated chip that drives the photonic integrated chip; and
an interposer that electrically couples the photonic integrated chip and the electronic integrated chip,
wherein the photonic integrated chip is provided on a side of a first main surface of the interposer,
the electronic integrated chip is provided on a side of a second main surface on an opposite side of the first main surface, and
the interposer includes
a power supply layer,
a first power supply via coupled to the power supply layer and configured to supply a first power supply voltage to the photonic integrated chip, and
a second power supply via coupled to the power supply layer and configured to supply a second power supply voltage to the electronic integrated chip,
wherein the power supply layer of the interposer is coupled to a second power supply layer formed in the main board.

9. The optical communication device according to claim 8, wherein
the photonic integrated chip and the interposer of the optical module partially overlap in a stacking direction,
the main board has a step in a mounting surface to which the optical module is mounted, and
the interposer is bonded to the mounting surface of the main board in a region that does not overlap the photonic integrated chip, and the photonic integrated chip is positioned at the step of the main board.

10. The optical communication device according to claim 8, wherein
the interposer of the optical module has a step in the first main surface, and the photonic integrated chip of the optical module is provided at the step, and
the electronic integrated chip of the optical module is coupled to a signal line of the main board by a via wiring that penetrates the interposer.
